(19) United States
(12) Patent Application Publication
(10) Pub. No.: US 2006/0244371 A1
(43) Pub. Date: Nov. 2, 2006

(54) OLED device having improved lifetime and output

(75) Inventors: Ronald S. Cok, Rochester, NY (US); Lee W. Tutt, Webster, NY (US); Donald R. Preuss, Rochester, NY (US); Joel D. Shore, Rochester, NY (US); Yuan-Sheng Tyan, Webster, NY (US); Giuseppe Farruggia, Webster, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/218,249

(22) Filed: Sep. 1, 2005

Related U.S. Application Data
(63) Continuation-in-part of application No. 11/119,671, filed on May 2, 2005.

(51) Int. Cl. H01L 51/00

(52) U.S. Cl. 313/506

(57) ABSTRACT

An organic light-emitting diode (OLED) device, comprising: a) a first OLED element; b) a second OLED element formed over the first OLED element; and c) a scattering layer optically coupled to the first and/or the second OLED elements; wherein the first and second OLED elements each include first and second spaced-apart conductors with one or more organic layers formed there-between, at least one organic layer of each of the first and second OLED elements being a light-emitting layer.

### CROSS REFERENCE TO RELATED APPLICATIONS

This application is a continuation-in-part of copending, commonly assigned U.S. Ser. No. 11/119,671, filed May 2, 2005, the disclosure of which is incorporated herein by reference.

### FIELD OF THE INVENTION

The present invention relates to organic light-emitting diode (OLED) devices and, more particularly, to an OLED device having improved lifetime and light output.

### BACKGROUND OF THE INVENTION

Organic light-emitting diode (OLED) devices, also referred to as organic electroluminescent (EL) devices, have numerous well-known advantages over other flat-panel display devices currently in the market place. Among the potential advantages is brightness of light emission, relatively wide viewing angle, reduced device thickness, and reduced electrical power consumption compared to, for example, liquid crystal displays (LCDs) using backlighting.

Applications of OLED devices include active-matrix image displays, passive-matrix image displays, and area-lighting devices such as, for example, selective desktop lighting. Irrespective of the particular OLED device configuration tailored to these broad fields of applications, all OLEDs function on the same general principles. An organic electroluminescent (EL) medium structure is sandwiched between two electrodes. At least one of the electrodes is at least partially light transmissive. These electrodes are commonly referred to as an anode and a cathode in analogy to the terminals of a conventional diode. When an electrical potential is applied between the electrodes so that the anode is connected to the positive terminal of a voltage source and the cathode is connected to the negative terminal, the OLED is said to be forward biased. Positive charge carriers (holes) are injected from the anode into the EL medium structure, and negative charge carriers (electrons) are injected from the cathode. Such charge carrier injection causes current flow from the electrodes through the EL medium structure. Recombination of holes and electrons within a zone of the EL medium structure results in emission of light from this zone that is, appropriately, called the light-emitting zone or interface. The organic EL medium structure can be formed of a stack of sublayers that can include small molecule layers or polymer layers. Such organic layers and sublayers are well known and understood by those skilled in the OLED art.

Full-color OLED devices may employ a variety of organic materials to emit different colors of light. In this arrangement, the OLED device is patterned with different sets of organic materials, each set of organic materials associated with a particular color of light emitted. Each pixel in an active-matrix full-color OLED device typically employs each set of organic materials, for example to form a red, green, and blue sub-pixel. The patterning is typically done by evaporating layers of organic materials through a mask. In an alternative arrangement, a single set of organic materials emitting broadband light may be deposited in continuous layers with arrays of differently colored filters employed to create a full-color OLED device.

The emitted light is directed towards an observer, or towards an object to be illuminated, through the light transmissive electrode. If the light transmissive electrode is between the substrate and the light emissive elements of the OLED device, the device is called a bottom-emitting OLED device. Conversely, if the light transmissive electrode is not between the substrate and the light emissive elements, the device is referred to as a top-emitting OLED device. The present invention may be directed to either a top-emitting or bottom-emitting OLED device. In top-emitting OLED devices, light is emitted through an upper electrode or top electrode, typically but not necessarily the cathode, which has to be sufficiently light transmissive, while the lower electrode(s) or bottom electrode(s), typically but not necessarily the anode, can be made of relatively thick and electrically conductive metal compositions which can be optically opaque. Because light is emitted through an electrode, it is important that the electrode through which light is emitted be sufficiently light transmissive to avoid absorbing the emitted light. Typical prior-art materials proposed for such electrodes include indium tin oxide (ITO) and very thin layers of metal, for example silver, aluminum, magnesium or metal alloys including these metals.

OLED devices age as current passes through the emissive materials of the display. Specifically, the emissive materials age in direct proportion to the current density passing through the materials. One approach to dealing with the aging problem, while maintaining the resolution of the display, is to stack two or more OLED light emitting elements on top of each other thereby allowing the areas of the light-emitting elements to be larger to improve lifetime, and/or allowing more pixels to be provided for a given area, thereby improving resolution. This approach is described in U.S. Pat. No. 5,703,436 by Forrest et al., issued Dec. 30, 1997, and U.S. Pat. No. 6,274,980 by Burrows et al., issued Aug. 14, 2001. Stacked OLEDs utilize a stack of light emitting elements located one above another over a substrate. Each light-emitting element may share one or both electrodes with a neighboring light emitting element in the stack and each electrode is individually connected to an external power source, thereby enabling individual control of each light-emitting element.

In an alternative stacking structure, electrodes at the top and bottom of the stack are connected to external power sources but the internal electrodes between the stacked light emitting elements are not connected externally. Hence, the same current flows through all of the light-emitting elements at once. Although this does not allow each of the light-emitting elements in the stack to be separately controlled, such a design is much easier to construct and each of the light-emitting elements will emit light in response to the current, providing a brighter light output for a given current or, conversely, the current density may be reduced for a given desired brightness, thereby improving the lifetime of the OLED device. U.S. Pat. No. 6,903,378 discloses a white-light emitting OLED device with two cascaded OLED elements joined by a common, doped organic conductor layer. US 2005/0029933 likewise discloses a cascaded OLED device wherein the at least two cascaded OLED elements emit light of different colors.

U.S. Patent Application Publication 2004/0227460 A1, entitled “Cascaded Organic Electroluminescent Device Having Connecting Units With N-Type And P-Type Organic Layers”, the disclosure of which is herein incorporated by reference, teaches tandem OLED devices wherein each organic EL unit is preferably placed at independently tuned optical locations. While such independent tuning can improve total light output, it also imposes strict design requirements and manufacturing tolerances on the thicknesses of the layers of the OLED device that may be difficult to meet, and may cause an increased variability in angular dependence on frequency of light emission.

Referring to FIG. 2, a top-emitting OLED device as suggested by the prior art is illustrated having a substrate 10 (either reflective, transparent, or opaque). Over the substrate 10, a semiconducting layer is formed providing thin-film electronic components 30 for driving an OLED. An interlayer insulating and planarizing layer 32 is formed over the thin-film electronic components 30 and a patterned reflective electrode 12 defining OLED light-emissive elements is formed over the insulating layer 32. An inter-pixel insulating film 34 separates the elements of the patterned reflective electrode 12. One or more first layers 14a of organic material, one of which emits light, are formed over the patterned reflective electrode 12. A transparent second electrode 16, one or more second layers 14b of organic material, one of which emits light, and a transparent third electrode 18 are formed over the one or more first layers 14a of organic material. A gap 19 separates the transparent third electrode 18 from an encapsulating cover 20. The encapsulating cover 20 is transparent and may be coated directly over the transparent electrode 18 so that no gap 19 exists. In some prior-art embodiments, the first electrode 12 may instead be at least partially transparent and/or light absorbing.

A typical top-emitter OLED device as proposed in the art uses a glass substrate, a reflective conducting first electrode 12 comprising a metal, for example aluminum, a stack of organic layers, and transparent second and third electrode layers 16 and 18, employing, for example indium-tin-oxide (ITO). Light generated from the device is emitted through the transparent electrodes 16 and 18. In these typical devices, the index of the ITO layers, the organic layers, and the glass is about 2.0, 1.7, and 1.5 respectively. It has been estimated that nearly 50% of the generated light is trapped by internal reflection in the ITO/organic EL element, 25% is trapped in the glass substrate, and only about 25% of the generated light is actually emitted from the device and performs useful functions.

A variety of techniques have been proposed to improve the out-coupling of light from thin-film light emitting devices. For example US 2004/0140757 and 2004/0155576 describe microcavity OLED devices wherein one of the electrode layers is semitransparent and reflective and the other one is essentially opaque and reflective thereby forming an optical cavity that serves to amplify the desired light output. The disclosures also describe a high-index absorption-reduction layer next to the semitransparent electrode layer outside the microcavity used to further improve the performance of the microcavity OLED device. However, the color of light output by such designs has a significant dependence on angle, rendering them unsuitable for many applications. Moreover, such designs require carefully optimized layer thicknesses to achieve the desired effect. Such restrictions on layer thickness create considerable difficulty and cost in manufacturing.

Another approach to improving the light output from an OLED device is disclosed in Chou (International Publication Number WO 02/37580 A1) and Liu et al. (U.S. Patent Application Publication No. 2001/0026124 A1), which teach the use of a volume or surface scattering layer to improve light extraction. The scattering layer is applied next to the organic layers or on the outside surface of the glass substrate and has an optical index that matches these layers. Light emitted from the OLED device at higher than critical angle that would have otherwise been trapped can penetrate into the scattering layer and be scattered out of the device. The efficiency of the OLED device is thereby improved but trapped light may propagate a considerable distance horizontally through the cover, substrate, or organic layers before being scattered out of the device, thereby reducing the sharpness of the device in pixellated applications such as displays. Referring to FIG. 9, e.g., the sharpness of a bottom-emitting active matrix OLED device employing a light-scattering layer coated on the substrate is illustrated. The average MTF (sharpness) of the device (in both horizontal and vertical directions) is plotted for an OLED device with the light-scattering layer and without the light scattering layer. As is shown, the device with the light-scattering layer is much less sharp than the device without the light scattering layer, although more light was extracted (not shown) from the OLED device with the light-scattering layer. FIG. 9 thus illustrates the reduction in sharpness that occurs when scattering layers are employed as taught in the prior art.

US 2005/0073228 describes a white light emitting OLED device that combines a microcavity OLED device with a light-integrating element to reduce the angular dependence of the color of light output. However, such a design is still limited by manufacturing tolerance difficulties.

There is a need therefore for an improved organic light-emitting diode device structure that increases the light output and improves lifetime.

### SUMMARY OF THE INVENTION

In accordance with one embodiment, the invention is directed towards an organic light-emitting diode (OLED) device, comprising:

a) a first OLED element;

b) a second OLED element formed over the first OLED element; and

c) a scattering layer optically coupled to the first and/or the second OLED elements;

wherein the first and second OLED elements each include first and second spaced-apart conductors with one or more organic layers formed there-between, at least one organic layer of each of the first and second OLED elements being a light-emitting layer.

### ADVANTAGES

The present invention has the advantage that it increases the light output from, and lifetime of, an OLED device while reducing the cost of manufacturing the OLED device.

### BRIEF DESCRIPTION OF THE DRAWINGS

FIG. 1 illustrates a cross section of a top-emitter OLED device having a reflective scattering layer according to one embodiment of the present invention;

FIG. 2 illustrates a cross section of a prior-art top-emitter OLED device;

FIG. 3 illustrates a cross section of a top-emitter OLED device having a transmissive scattering layer according to another embodiment of the present invention;

FIG. 4 illustrates a cross section of a top-emitter OLED device having independently controlled OLED elements in separate layers according to another embodiment of the present invention;

FIG. 5 illustrates a cross section of a top-emitter OLED device having a scattering element located between the OLED elements according to yet another embodiment of the present invention;

FIG. 6 illustrates a cross section of a top-emitter OLED device having a shared conductive scattering layer according to yet another embodiment of the present invention;

FIG. 7 illustrates a cross section of a top-emitter OLED device having a plurality of scattering layers according to yet another embodiment of the present invention;

FIG. 8 illustrates a cross section of a bottom-emitter OLED device according to yet another embodiment of the present invention; and

FIG. 9 is a graph illustrating the loss in sharpness of prior-art OLED devices employing a scattering layer.

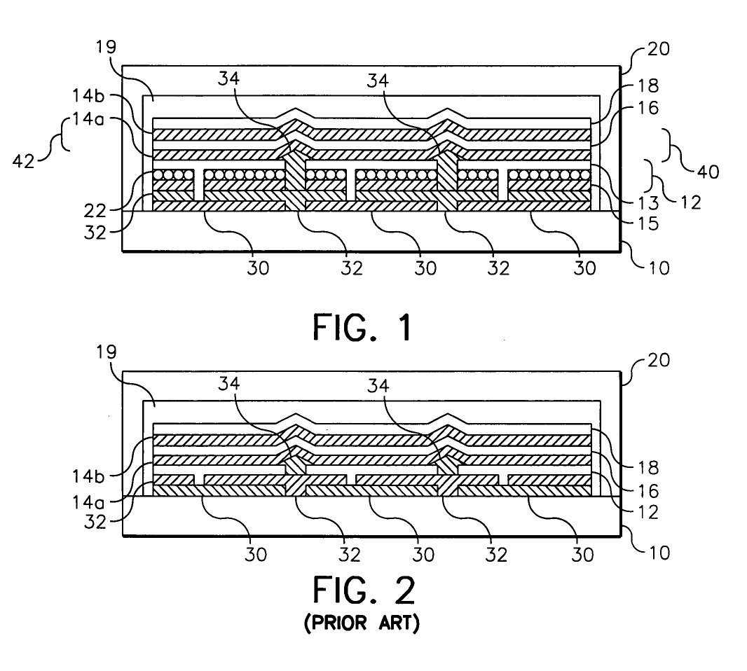

It will be understood that the figures are not to scale since the individual layers are too thin and the thickness differences of various layers too great to permit depiction to scale.

### DETAILED DESCRIPTION OF THE INVENTION

Referring to FIG. 1, in accordance with one embodiment of the present invention, an organic light-emitting diode (OLED) device comprises a first OLED element 40 formed over a substrate 10, a second OLED element 42 formed over the first OLED element 40, a scattering layer 22 optically coupled to the first and/or the second OLED element 40 or 42. The first and second OLED elements 40 and 42 each include first and second spaced-apart conductors with one or more organic layers formed there-between, at least one organic layer of each of the first and second OLED elements 40 and 42 being a light-emitting layer. As illustrated in FIG. 1, the first OLED element 40 has first and second spaced-apart transparent conductors 13 and 16 and organic layers 14a. The second OLED element 42 has first and second spaced-apart transparent conductors 18 and 16 and organic layers 14b. In this embodiment, the conductor 16 is shared between the OLED elements 40 and 42. Conductor 13 is patterned to form individual pixels. A reflector 15, for example a layer of aluminum, silver, or magnesium or alloys thereof, reflects light that passes through the transparent conductor 13. In FIG. 1, scattering layer 22 is located between the transparent conductor 13 and the reflector 15. Depending on the location of the scattering layer 22, the scattering layer 22 may be a reflective scattering layer or a transmissive scattering layer. An encapsulating cover 20 is affixed to the substrate 10 and protects the OLED device, forming a gap 19 between the OLED element 42 and the cover 20.

The conductors 13, 16, or 18 may be externally connected electrodes and thereby form separately controlled OLED elements 40 and 42. Alternatively, conductor 16 may not be externally connected and may comprise doped organic materials, metals, or other conductors or combinations of conductors so that OLED elements 40 and 42 are controlled together. The conductors may be formed in combination with reflectors (e.g. reflective layer 15) or scattering layers (e.g. scattering layer 22). Alternatively, the conductors may themselves be reflective and/or scattering or formed in a plurality of layers. For example, transparent conductor 13 may be combined with reflector 15 to form a reflective conductor 12.

In a preferred embodiment useful for display devices, the organic light emitting diode (OLED) device comprises a substrate 10; a first OLED element 40 formed on the substrate 10; a second OLED element 42 formed over the first OLED element 40; a cover 20 provided over the first and second OLEDs 40 and 42; a scattering layer 22 optically coupled with the first and/or the second OLED elements 40 or 42; and wherein the first and second OLED elements 40 and 42 each include first and second spaced-apart conductors with one or more organic layers formed there-between, at least one organic layer of each of the first and second OLED elements being a light-emitting layer and wherein the first and second OLED elements 40 and 42 have a first optical index range; and wherein light emitted by the first and second OLED elements 40 and 42 is emitted through either the cover 20 or the substrate 10, the cover 20 or substrate 10 through which light is emitted having a second optical index; and wherein a low-index element 19 is formed between the scattering layer 22 and the cover 20 or substrate 10 through which light is emitted, the low-index element 19 having a third optical index lower than either of the first optical index range or the second optical index. The low-index element may be a gap filled with a gas (e.g. air or an inert gas such as argon or nitrogen) or a solid material having a third optical index (e.g. a polymer).

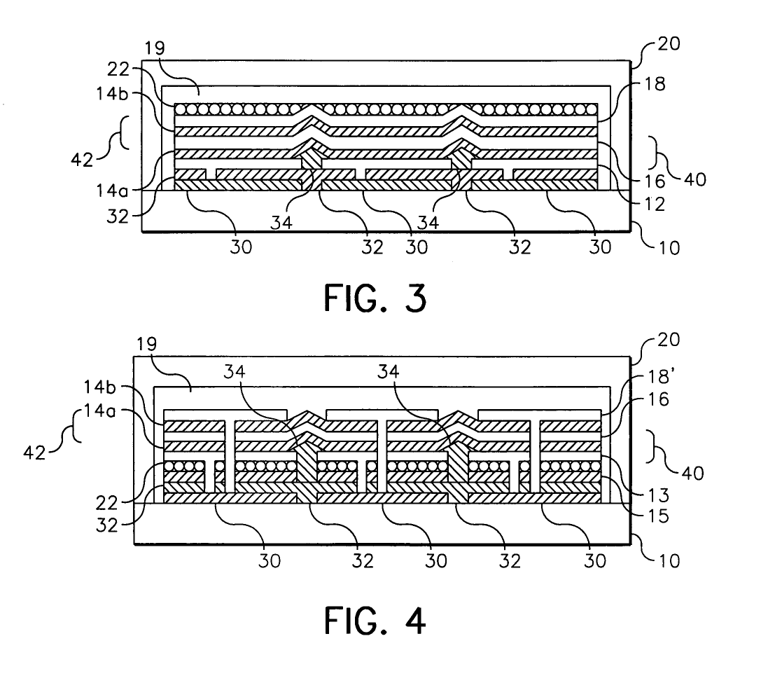

In an alternative embodiment shown in FIG. 3, the scattering layer 22 is formed over the transparent conductor 18 of the second OLED element 42. In this embodiment, the reflective conductor 12 may be formed of a single reflective and conductive metal layer, for example silver, aluminum, magnesium or other metals or metal alloys.

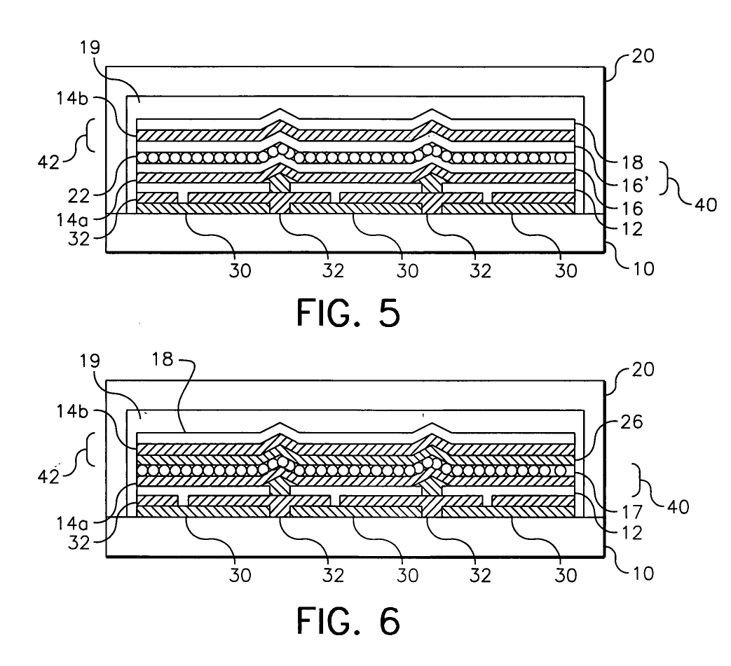

As illustrated in FIGS. 1 and 3, the second OLED element 42 does not have patterned conductors forming individual pixels. However, in an alternative embodiment, both the first and second OLED elements 40 and 42 have at least one patterned conductor, allowing independent control of separate pixels formed in each OLED element. Referring to FIG. 4, the conductor 18′ is patterned and connected to the thin-film electronic circuitry 30.

In an alternative embodiment shown in FIG. 5, the scattering layer 22 is formed between the first and second OLED elements 40 and 42. In this embodiment, the scattering layer 22 need not be conductive and separate conductors 16 and 16′ are employed in the first and second OLED elements 40 and 42 respectively. Referring to the alternative embodiment shown in FIG. 6, the scattering layer 17 is conductive and actually forms conductors shared by the first and second OLED elements 40 and 42. In this embodiment, because the scattering layer may form a rough surface, an additional high-resistance, performance-enhancing layer 26 is employed in the second OLED element 42 to reduce the severity and likelihood of shorting between electrode layers 17 and 18. Such high-resistance, performance-enhancing layers are described in commonly assigned, co-pending U.S. Ser. No. 10/822,517, the disclosure of which is hereby incorporated by reference in its entirety, and may be employed in any embodiment of the present invention where the scattering layer may form a rough surface on which subsequent organic or conducting layers are formed, for example in the configurations of FIGS. 1, 4, 5, and 6. Such performance-enhancing high-resistance layers may have an intermediate through resistivity of 10⁻⁴ to 10² ohm-cm², with higher values being desired for smaller pixel sizes.

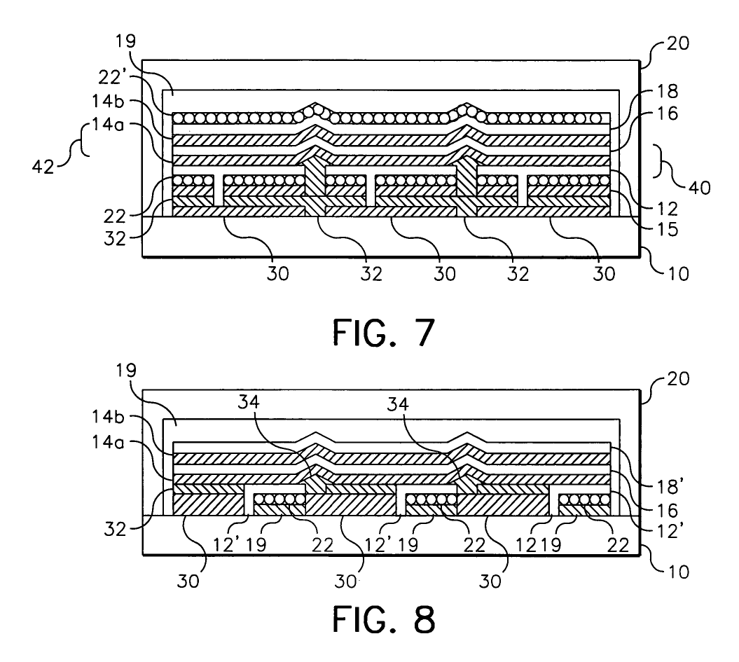

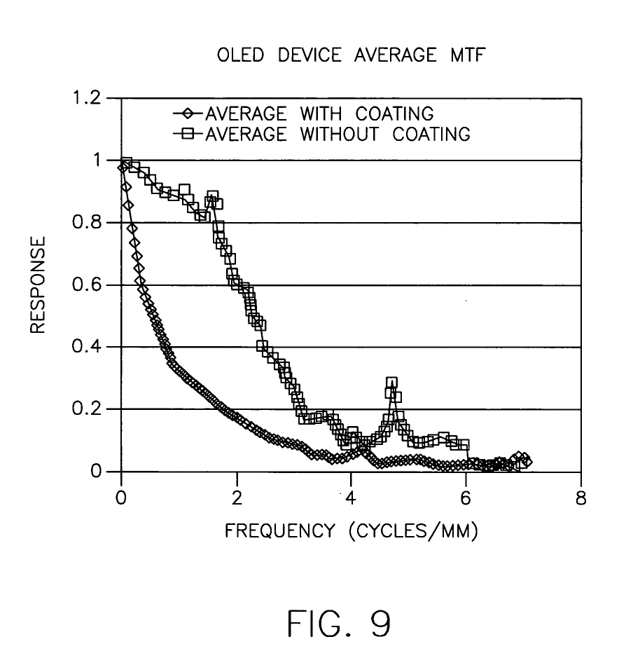

The present invention is not limited to embodiments having only one scattering layer. Referring to FIG. 7, scattering layer 22 is employed in optical contact with OLED element 40 while scattering layer 22′ is employed in optical contact with OLED element 42. Nor is the present invention is limited to top-emitter embodiments emitting light through the cover 20. Referring to FIG. 8, a bottom-emitting embodiment is depicted, wherein electrode 12′ is transparent while electrode 18′ may be reflective. Light emitted by the OLED elements 40 and 42 may be emitted through the substrate 10.

As indicated above, the shared conductor 16 may be externally connected to a power supply, as may be the conductors 12 and 18. Such a conductor may comprise metals or conductive organic materials, including polymers, or combinations or layers of such conductive materials. In the embodiment of FIG. 4, the shared conductor 16 is most advantageously connected to a power supply to enable independent control of the first and second OLED elements 40 and 42, thereby increasing the resolution and/or lifetime of the OLED device. However, in an alternative embodiment, a shared electrode may not be externally connected and both OLED elements 40 and 42 may be controlled through a common patterned conductor, for example electrode 12 as illustrated in FIG. 1. Such a configuration may improve the lifetime of an OLED device by reducing the required current density through the combined OLED elements to produce the same amount of light as a single OLED element with twice the current density.

When an conductor is shared between two OLED elements, the stacks of organic materials are typically inverted with respect to each other, that is the bottom OLED element may have a conductor, for example an anode, nearest the substrate and a cathode furthest from the substrate. In contrast, the top OLED element will have the cathode nearest the substrate (shared with the bottom OLED element), the anode furthest from the substrate, and the organic layers in inverted order. When no conductor is shared, such a requirement is not necessary, but may be employed, if desired.

In operation, the conductors 12 and 18, and possibly 16, provide power through the thin-film circuitry 30 to the organic layers 14a and 14b, causing them to emit light. Some of the light is emitted from the device, but some of the light is optically trapped within the OLED elements. The trapped light is scattered by the scattering layer 22 and scattered either out of the device or back into the OLED elements. The light scattered back into the OLED elements is then reflected by reflector 15 or reflective electrode 12 and is scattered again by scattering layer 22 until the light is either absorbed within the OLED elements or scattered out of the device.

The present invention not only provides improved light output, but also decreases the sensitivity of the OLED element performance to layer thicknesses and thus reduces manufacturing costs. Because the scattering layer 22 has the effect of destroying optical cavity effects, standing waves between the various layers of an OLED element are not formed. While such standing waves can be useful in a conventional OLED, such optical cavity effects impose strict manufacturing tolerances on the OLED device and cause an angular dependence on frequency of light emission. Applicants have demonstrated this tradeoff by producing two different, simple OLED structures employing the same materials, with the only difference being the thicknesses of an organic material layer. As shown in the table below, the light output from the devices without the scattering layer depends greatly on the layer thickness, while the light output from the devices with the scattering layer does not show such a great dependence.

TABLE 1

| | |
|---|---|
| Structure 1 | Structure 2 |
| (cd/m² light output) | (cd/m² light output) |

| | | |
|---|---|---|
| Without Scattering Layer | 224 | 591 |
| With Scattering Layer | 1121 | 1138 |

As discussed in copending, commonly assigned U.S. Ser. No. 11/119,671, filed May 2, 2005, incorporated by reference above, the use of a scattering layer in a tandem OLED device randomizes the angle of the emitted light, such that the oscillation of light output intensity with the distance between a light-emitting junction of a light-emitting layer and a reflecting electrode is mostly reduced and the light-emitting junctions do not have to be restricted to anti-node locations. In addition to decreasing the sensitivity of the OLED element performance to layer thicknesses and thus reduces manufacturing costs, this also permits the light-emitting junctions of the light-emitting layers of the EL units of a tandem structure to be placed closer to each other (e.g., less than 90 nanometers) than taught in the prior art to reduce the voltage needed to drive the device.

As employed herein, a light scattering element is an optical layer or surface that tends to randomly redirect any light that impinges on the layer or surface from any direction. The light scattering element 22 is optically integrated into the OLED device for scattering light emitted by the light-emitting layers and reflected by the reflective electrode 12 or reflector 15. The presence of an optically integrated scattering layer 22 in accordance with the present invention defeats total internal reflection of emitted light that might otherwise propagate between and in the electrodes and organic layers of each OLED element.

Although not illustrated, the light scattering element 22 may also be located between the electrodes of each OLED element. Optical integration means that light emitted by an OLED element is redirected. For example, a light scattering element integrated into a reflective electrode or reflector may scatter the reflected light and may be constructed with a rough surface rather than a smooth planar surface. If the light scattering element is integrated into a transparent layer, the light scattering element scatters the light that passes through the layer.

The use of a transparent low-index element having a refractive index lower than the refractive index of the encapsulating cover or substrate through which light is emitted from the OLED device and lower than the refractive index range of the OLED element materials to enhance the sharpness of an OLED device having a scattering element is described in co-pending, commonly assigned U.S. Ser. No. 11/065,082, filed Feb. 24, 2005, the disclosure of which is hereby incorporated by reference, and may be employed in concert with the present invention. For example, as illustrated in FIGS. 1 and 3-7, a transparent low-index layer 19 (possibly an air gap) having a refractive index lower than the refractive index of the cover 20 and lower than refractive index range of the organic layers 14a and 14b may be located between the scattering element 22, 17 and the encapsulating cover 20. Since the low-index gap 19 has an optical index lower than that of the OLED elements and the cover 20, any light that is scattered into the gap 19 by the scattering layer will pass through the gap and the cover 20, since light passing from a low-index material (the gap 19) into a higher index material (the cover 20) cannot experience total internal reflection. Alternatively, as illustrated in FIG. 8, a low-index layer 19 may be employed under the scattering layer 22 in a bottom-emitting embodiment.

Because a shared conductor (e.g. 16) or additional layers of material between separate conductors of the OLED elements may have a lower optical index than the organic materials in the layers 14, the light emitted by each OLED element may experience total internal reflection separately in each OLED element. Hence, a scattering layer optically coupled to one OLED element may not be optically coupled to the second OLED element. To extract light that is separately totally internally reflected within each OLED element, a scattering layer (22 and 22′) may be associated with each OLED element (40 and 42 respectively), as illustrated in FIG. 7.

Reflective conductors are preferably made of metal, metal oxides, or metal alloys, for example aluminum, silver, ytterbium, magnesium silver, or indium tin oxide, or combinations of layers of such materials, and may incorporate other dopants and/or layers such as lithium and molybdenum to enhance the conductivity or electron-injection capabilities of the electrode.

Scattering element 22 may comprise a volume scattering layer or a surface scattering layer. In certain embodiments, e.g., scattering element 22 may comprise materials having at least two different refractive indices. The scattering element 22 may comprise, e.g., a matrix of lower refractive index and scattering elements having a higher refractive index. Alternatively, the matrix may have a higher refractive index and the scattering elements may have a lower refractive index. For example, the matrix may comprise silicon dioxide or cross-linked resin having indices of approximately 1.5, or silicon nitride with a much higher index of refraction. If scattering element 22 has a thickness greater than approximately one-tenth the wavelength of the emitted light, then it is desirable for the index of refraction of at least one material in the scattering element 22 to be approximately equal to or greater than the refractive indices of the organic layers 14. This is to insure that all of the light trapped in the organic and conductor layers can experience the direction altering effects of scattering element 22. If scattering element 22 has a thickness less than approximately one-tenth the wavelength of the emitted light, then the materials in the scattering layer need not have such a preference for their refractive indices.

The scattering layer 22 can employ a variety of materials. For example, randomly located spheres of titanium dioxide may be employed in a matrix of polymeric material. Alternatively, a more structured arrangement employing ITO, silicon oxides, or silicon nitrides may be used. In a further embodiment, the refractive materials may be incorporated into the electrode itself so that the electrode is a scattering layer. Shapes of refractive elements may be cylindrical, rectangular, or spherical, but it is understood that the shape is not limited thereto. The difference in refractive indices between materials in the scattering layer 22 may be, for example, from 0.3 to 3, and a large difference is generally desired. The thickness of the scattering layer, or size of features in, or on the surface of, a scattering layer may be, for example, 0.03 to 50 μm. It is generally preferred to avoid diffractive effects in the scattering layer. Such effects may be avoided, for example, by locating features randomly or by ensuring that the sizes or distribution of the refractive elements are not the same as the wavelength of the color of light emitted by the device from the light-emitting area.

The scattering layer 22 should be selected to get the light out of the OLED as quickly as possible so as to reduce the opportunities for re-absorption by the various layers of the OLED device. If the scattering layer 22 is to be located between the organic layers 14a and 14b and the transparent low-index element 19, or between the organic layers 14a and 14b and a reflective electrode 12, then the total diffuse transmittance of the same layer coated on a glass support should be high (preferably greater than 80%). In other embodiments, where the scattering layer 22 is itself desired to be reflective, then the total diffuse reflectance of the same layer coated on a glass support should be high (preferably greater than 80%). In all cases, the absorption of the scattering layer should be as low as possible (preferably less than 5%, and ideally 0%).

Materials of the light scattering layer 22 can include organic materials (for example polymers or electrically conductive polymers) or inorganic materials. The organic materials may include, e.g., one or more of polythiophene, PEDOT, PET, or PEN. The inorganic materials may include, e.g., one or more of SiOₓ (x>1), SiNₓ (x>1), Si₃N₄, TiO₂, MgO, ZnO, Al₂O₃, SnO₂, In₂O₃, MgF₂, and CaF₂. The scattering layer 22 may comprise, for example, silicon oxides and silicon nitrides having a refractive index of 1.6 to 1.8 and doped with titanium dioxide having a refractive index of 2.5 to 3. Polymeric materials having refractive indices in the range of 1.4 to 1.6 may be employed having a dispersion of refractive elements of material with a higher refractive index, for example titanium dioxide.

Referring back to FIG. 1, an embodiment of the present invention having a scattering element 22 between reflector 15 and transparent conductor 13 is illustrated. In the embodiment of FIG. 1, photolithographic processes may be employed to create scattering structures in the scattering element 22. Conventional lithographic means can be used to create the scattering layer using, for example, photo-resist, mask exposures, and etching as known in the art. Alternatively, coating may be employed in which a liquid, for example polymer having a dispersion of titanium dioxide, may form a scattering element 22. Applicants have demonstrated both the use of a dispersion of titanium dioxide in a solvent coated over an OLED elements (as shown in FIG. 3) and the use of a reflective scattering element under a transparent electrode (as shown in FIG. 1) to improve the light extraction of an OLED device. Inkjet deposition of scattering layers has also been demonstrated.

In the embodiments in which the scattering layer 22 is formed between the OLED elements 40 and 42 (for example as illustrated in FIG. 6), the scattering layer 22 may be conductive. Such a conductive scattering layer may be formed by coating scattering particles with a conductive, reflective material, such as metal, or by employing a matrix of conductive, transparent material (for example ITO or conductive polymers) in which the scattering particles are embedded, or by employing conductive scattering particles. Alternatively, as illustrated in FIG. 5, the scattering layer may not be conductive if the conductors 16 and 16′ are connected to an external power supply or are provided with vias to connect the electrodes together or are connected at other locations, for example on the perimeter of the OLED device (not shown).

The present invention can employ inorganic (for example metallic) or organic conductors between the OLED elements, with or without dopants. To function efficiently, an organic conductor for the cascaded OLED elements should provide electron injection into the electron-transporting layer and hole injection into the hole-transporting layer of the two adjacent organic EL units. A variety of materials may be used to form the organic electrodes. In preferred embodiments, organic electrode materials are selected to provide high optical transparency and excellent charge injection, thereby providing the cascaded OLED element stack high electroluminescence efficiency and operation at an overall low driving voltage.

The organic electrode may comprise doped organic connectors provided between adjacent organic EL units. Each doped organic connector may include at least one n-type doped organic layer, or at least one p-type doped organic layer, or a combination of layers, thereof. Preferably, the doped organic connector includes both an n-type doped organic layer and a p-type doped organic layer disposed adjacent to one another to form a p-n heterojunction. It is also preferred that the n-type doped organic layer is disposed towards the anode side, and the p-type doped organic layer is disposed towards the cathode side. The choice of using n-type doped organic layer, or a p-type doped organic layer, or both (the p-n junction) is in part dependent on the organic materials that include the organic EL units. Each connector can be optimized to yield the best performance with a particular OLED element. This includes choice of materials, layer thickness, modes of deposition, and so forth. Further details of suitable organic connectors are disclosed in US 2005/0029933, the disclosure of which is hereby incorporated by reference in its entirety.

While the above described illustrated embodiments depict first and second OLED elements 40 and 42, in further embodiments of the present invention, additional (e.g., third, fourth, fifth, etc.) OLED elements may be included over or under such first and second OLED elements such that more than two OLED elements may be provided in a stack, with scattering layers located between OLED elements or on the top or bottom electrodes of the stack. The stacked OLED elements may be controlled as a group (or sub-group) with common electrodes, as individual elements employing individual electrodes, or as a combination thereof.

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890 issued May 8, 2001 to Boroson et al. In addition, barrier layers such as SiOₓ (x>1), Teflon, and alternating inorganic/polymeric layers are known in the art for encapsulation. In particular, very thin layers of transparent encapsulating materials may be deposited on the conductor 18 to protect the conductor 18. Such layers may also provide optical functions, such as reduction of absorption of light in semi-transmissive electrodes. Materials such as parylene, ITO, or aluminum oxide deposited, for example, using spin coating or atomic layer deposition, are suitable.

In one embodiment of the present invention, the organic layers may be patterned with a variety of organic materials and, when current is passed through the layers, produce a variety of colored light defining the colored sub-pixels of a full-color OLED device. In an alternative embodiment, the light emitted from the light-emitter layers may be broadband light, for example white, and color filters may be located over the light-emitting layers 14 to provide different colors of light. Color filters may be formed on the inside or outside of the cover or, alternatively, on the electrode 18 or any protective layers formed over the electrode. The OLED elements may emit light of different colors, for example one OLED element may emit white light while the other OLED element may have patterned red, green, and blue pixels.

OLED devices of this invention can employ various well-known optical effects in order to enhance their properties if desired. This includes optimizing layer thicknesses to yield maximum light transmission, providing anti-glare or anti-reflection coatings over the display, or providing colored, neutral density, or color conversion filters over the display. Filters, and anti-glare or anti-reflection coatings may be specifically provided over the cover or as part of the cover.

The present invention may also be practiced with either active- or passive-matrix OLED devices. It may also be employed in display devices or in area illumination devices. In a preferred embodiment, the present invention is employed in a flat-panel OLED device composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light-emitting displays can be used to fabricate such a device, including both active- and passive-matrix OLED displays having either a top- or bottom-emitter architecture.

The invention has been described in detail with particular reference to certain preferred embodiments thereof, but it will be understood that variations and modifications can be effected within the spirit and scope of the invention.

### Parts List

10 substrate
12 patterned reflective conductor
12′ patterned transparent conductor
13 transparent conductor
14a, 14b organic layers
15 reflector
16, 16′ transparent conductor
17 conductive scattering layer
18 transparent conductor
18′ reflective conductor
19 low-index element
20 encapsulating cover
22, 22′ scattering layer
26 high resistance, performance-enhancing layer
30 thin-film circuitry
32 insulator
34 insulator
40 OLED element
42 OLED element

1. An organic light emitting diode (OLED) device, comprising:
a) a first OLED element;
b) a second OLED element formed over the first OLED element; and
c) a scattering layer optically coupled to the first and/or the second OLED elements;
wherein the first and second OLED elements each include first and second spaced-apart conductors with one or more organic layers formed there-between, at least one organic layer of each of the first and second OLED elements being a light-emitting layer.

2. The OLED device of claim 1, wherein the first and second OLED elements share a conductor.

3. The OLED device of claim 2 wherein the shared conductor is an electrode connected to an external power source.

4. The OLED device of claim 2 wherein the shared conductor is not connected to an external power source.

5. The OLED device of claim 4 wherein the shared conductor comprises an organic connective layer with or without doping materials.

6. The OLED device of claim 1 wherein at least one conductor of each OLED element is an electrode connected to an external power source.

7. The OLED device of claim 1 wherein at least one of the conductors comprises a metal, metal oxide, silver, aluminum, magnesium, alloys of silver, aluminum, or magnesium, or indium tin oxide or indium zinc oxide layer.

8. The OLED device of claim 1 wherein at least one of the conductors is patterned to form independently controllable light-emitting areas for at least one of the OLED elements.

9. The OLED device of claim 1 wherein the light-emitting organic layers of the first and second OLED elements emit the same color of light.

10. The OLED device of claim 1 wherein the light-emitting organic layers of the first and second OLED elements emit different colors of light.

11. The OLED device of claim 1 wherein the light-emitting organic layers of the first and/or second OLED elements emit substantially white light.

12. The OLED device of claim 1 wherein the first and second light-emitting organic layers emit complementary colors of light.

13. The OLED device of claim 1 wherein at least one of the conductors of the first or second OLED elements is at least partially reflective.

14. The OLED device of claim 1 wherein the scattering layer is in contact with a conductor, or forms a part of a conductor.

15. The OLED device of claim 1, further comprising a third OLED element formed over or under the first and second OLED elements.

16. The OLED device of claim 1, wherein the scattering layer is formed between the first and second OLED elements and is optically coupled to both the first and second OLED elements.

17. The OLED device of claim 1, wherein the scattering layer is formed as a part of a shared conductor of the first and second OLED elements and is optically coupled to both the first and second OLED elements.

18. The OLED device of claim 1, comprising one or more scattering layers optically coupled with each of the first and second OLED elements.

19. The OLED device of claim 1 wherein the OLED elements comprise materials having optical indices and layers thicknesses that in the absence of the scattering layer would form constructive optical interference that optimizes light output at a range of frequencies that does not correspond to the range of frequencies emitted by at least one of the OLED elements.

20. An organic light emitting diode (OLED) device, comprising:
a) substrate;
b) a first OLED element formed on the substrate;
c) a second OLED element formed over the first OLED element;
d) a cover provided over the first and second OLEDs; and
e) a scattering layer optically coupled with the first and/or the second OLED elements;
wherein the first and second OLED elements each include first and second spaced-apart conductors with one or more organic layers formed there-between, at least one organic layer of each of the first and second OLED elements being a light-emitting layer and wherein the first and second OLED elements have a first optical index range; and
wherein light emitted by the first and second OLED elements is emitted through either the cover or the substrate, the cover or substrate through which light is emitted having a second optical index; and
wherein a low-index element is formed between the scattering layer and the cover or substrate through which light is emitted, the low-index element having a third optical index lower than either of the first optical index range or the second optical index.
